(19) United States
(12) Patent Application Publication
(10) Pub. No.: US 2013/0303765 A1
(43) Pub. Date: Nov. 14, 2013

(54) PHENYLSILYL PHOSPHINE COMPOUND AND IRIDIUM COMPLEX MADE FROM THE SAME

(71) Applicant: NATIONAL TSING HUA UNIVERSITY, Hsinchu City (TW)

(72) Inventors: Yun CHI, Hsinchu City (TW); Shih-Han CHANG, Hsinchu City (TW); Kuan-Lin HUANG, Hsinchu City (TW)

(73) Assignee: NATIONAL TSING HUA UNIVERSITY, Hsinchu City (TW)

(21) Appl. No.: 13/796,148

(22) Filed: Mar. 12, 2013

(30) Foreign Application Priority Data
May 9, 2012 (TW) 101116494

(51) Int. Cl. H01L 51/00

(52) U.S. Cl. CPC H01L 51/0094
USPC 546/4; 556/404

(57) ABSTRACT

There are provided a phenylsilyl phosphine compound of formula (I) and an iridium complex of formula (II):

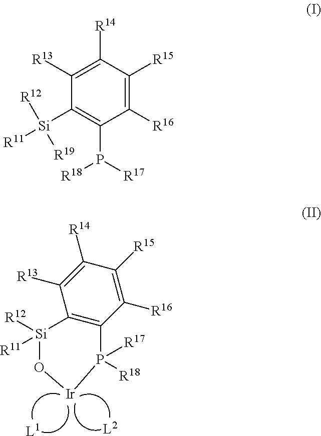

In formula (I) and formula (II), R¹¹-R¹⁹, L¹ and L² are defined according to the specification and the claims. The iridium complex made from the phenylsilyl phosphine compound of formula (I) has superior light-emitting efficiency.

### CROSS-REFERENCE TO RELATED APPLICATION

This application claims priority of Taiwanese Application No. 101116494, filed on May 9, 2012.

### BACKGROUND OF THE INVENTION

1. Field of the Invention

This invention relates to a phenylsilyl phosphine compound and an iridium complex made from the phenylsilyl phosphine compound.

2. Description of the Related Art

Organic electroluminescence devices have been gradually adopted into flat panel displays as light sources due to their advantages, such as self-illumination, superior light-emitting efficiency, low-voltage operation, and relatively high brightness. A conventional organic electroluminescence device usually includes an organic light-emitting diode (OLED) and a driving component. The light-emitting diode includes an organic layer which is used as an illuminating layer for emitting light. The organic layer is usually made of phosphorescent materials that are capable of emitting light via energy dissipation from their singlet excited states as well as triplet excited states, thereby improving light emitting efficiency of the OLED.

Taiwanese Patent Application Publication No. 201037057 discloses a phosphorescent tris-chelated transition metal complex represented by formulas (Ia), (Ib), (Ic), (Id), or their stereo isomers:

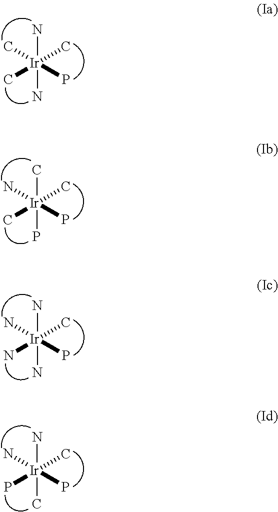

wherein the ĈN chelates or the N̂N chelates have a formula of Ar¹—Ar², Ar¹ representing aromatic ring or N-heterocyclic ring, Ar² representing N-heterocyclic ring. C in formula (Ia) as well as in formula (Ib) is a carbon atom contained in the aromatic ring of Ar¹, and N in formula (Ia), as well as in (Ib), is a nitrogen atom contained in Ar². N in formula (Ic), as well as in (Id), is a nitrogen atom contained in the heterocyclic ring of Ar¹ and Ar². The ĈP chelate in each formula has a formula of Ar³—(C(R^{a}R^{b}))ₘ—P(Ar⁴—Ar⁵), wherein m is 0, 1, or 2. Ar⁴ and Ar⁵ independently represent a phenyl group, a functionalized phenyl group, an iso-propyl group or a tert-butyl group. R^{a} and R^{b} independently represent H or a methyl group. —Ar³ represents

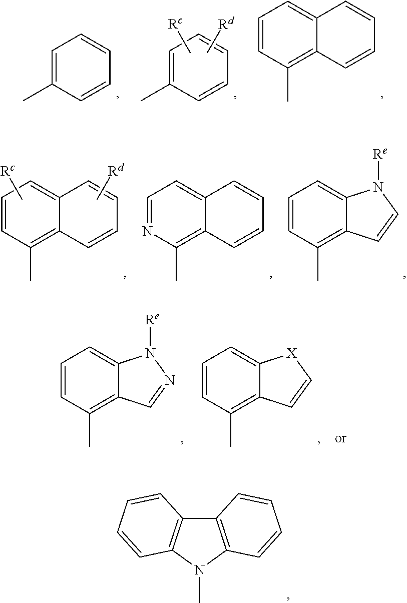

wherein R^{c} and R^{d} independently represent a methyl group, a cyano group, F or CₙF₂ₙ₊₁, n representing an integer ranging from 1 to 3. R^{e} represents a methyl group, a phenyl group, an alkyl group, a cyano group, or a functionalized aromatic group, and X represents O or S.

US Patent Application Publication No. 2008/0217582 discloses a phosphorescent iridium complex represented by formulas (Ie) and (If) below:

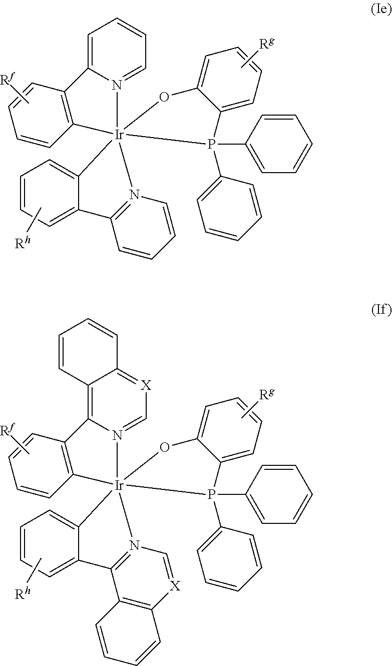

wherein R^{f} and R^{g} independently represent halogen or H, X representing carbon or nitrogen. Although the aforesaid iridium complex may be applied into an organic layer of the OLED, the quantum efficiency of the iridium complex is in a range from 0.09 to 0.19 that is undesirably low and needs to be improved.

Therefore, there is a need in the art to develop a new iridium complex with improved quantum efficiency, as well as a compound adapted for enhancing the quantum efficiency of the iridium complex when the compound is coordinated with a transition metal to form the iridium complex.

### SUMMARY OF THE INVENTION

Therefore, one object of the present invention is to provide a compound for enhancing the quantum efficiency of an iridium complex. Accordingly, a phenylsilyl phosphine compound of this invention is represented by formula (I):

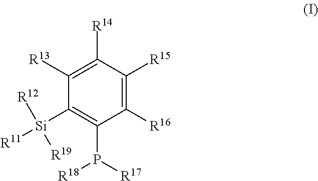

wherein:

R¹¹, R¹², R¹⁷, and R¹⁸ independently represent H, and alkyl group, or an aryl group;

R¹³, R¹⁴, R¹⁵, and R¹⁶ independently represent H or an organic group;

R¹⁹ represents H, or O—R²⁰; and

R²⁰ represents H or a leaving group.

Another object of the present invention is to provide an iridium complex having better quantum efficiency. Accordingly, an iridium complex of this invention is represented by formula (II):

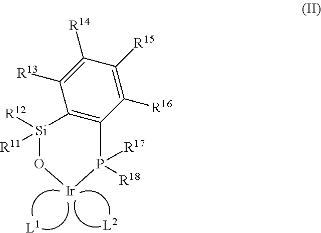

wherein:

R¹¹, R¹², R¹⁷, and R¹⁸ independently represent H, an alkyl group, or an aryl group;

R¹³, R¹⁴, R¹⁵, and R¹⁶ independently represent H or an organic group;

L¹ and L² independently represent

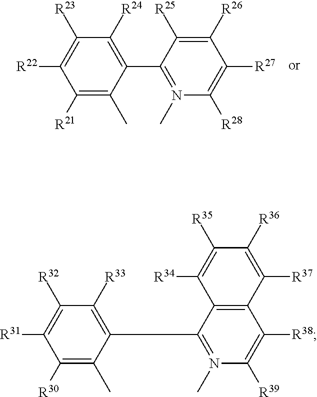

and

R²¹, R²², R²³, R²⁴, R²⁵, R²⁶, R²⁷, R²⁸, R³⁰, R³¹, R³², R³³, R³⁴, R³⁵, R³⁶, R³⁷, R³⁸, and R³⁹ independently represent H or an organic group.

### DETAILED DESCRIPTION OF THE PREFERRED EMBODIMENTS

According to the present invention, a phenylsilyl phosphine compound is represented by formula (I):

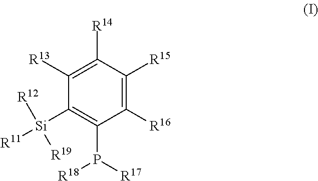

wherein:

R¹¹, R¹², R¹⁷, and R¹⁸ independently represent H, an alkyl group, or an aryl group;

R¹³, R¹⁴, R¹⁵, and R¹⁶ independently represent H or an organic group;

R¹⁹ represents H, or O—R²⁰; and

R²⁰ represents H or a leaving group.

Preferably, R¹¹ and R¹² independently represent H, a C₁-C₉ alkyl group, or an optionally substituted phenyl group. More preferably, R¹¹ and R¹² independently represent H, a methyl group or an optionally substituted phenyl group.

Preferably, R¹⁷ and R¹⁸ independently represent H, a C1-C9 alkyl group, or an optional substituted phenyl group. More preferably, R¹⁷ and R¹⁸ independently represent H, a methyl group or an optionally substituted phenyl group.

Preferably, the organic group is an electron withdrawing group or an electron donating group. The electron donating group is, but not limited to, a methyl group or a tert-butyl group. The electron withdrawing group is, but not limited to, halogen.

Examples of the phenylsilyl phosphine compound according the present invention include

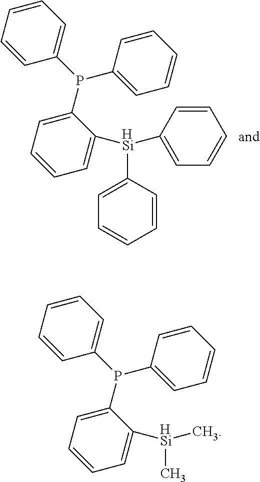

Different examples of the phenylsilyl phosphine compound of the present invention may be prepared by choosing respective reactants and under appropriate reaction conditions. A method for preparing the phenylsilyl phosphine compound of the present invention includes the following steps:

(1) reacting

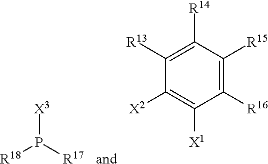

in an alkaline condition with existence of a catalyst under heating to form an intermediate; and

(2) reacting the intermediate and

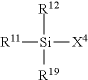

with existence of an organometallic reagent under heating to obtain the phenylsilyl phosphine compound, wherein X¹, X² and X³ represent halogen, X⁴ representing H or halogen. Preferably,

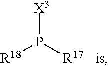

but not limited to, diphenyl phosphine or dimethyl phosphine. Preferably,

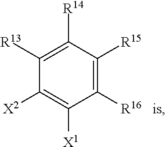

but not limited to, 1-bromo-2-iodobenzene. Preferably, the catalyst is tetrakis(triphenylphosphine)palladium (Pd(PPh₃)₄), cuprous iodide, bis(triphenylphosphine)palladium(II) dichloride (PdCl₂(PPh₃)₂), bis(tri-tert-butylphosphine)palladium, or combinations thereof. More preferably, the catalyst is Pd(PPh₃)₄. Preferably,

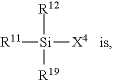

but not limited to, chlorodiphenylsilane.

Accordingly, an iridium complex of the present invention is represented by formula (II) below:

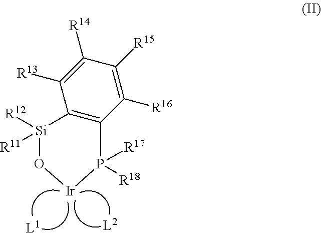

wherein:

R¹¹, R¹², R¹³, R¹⁴, R¹⁵, R¹⁶, R¹⁷, and R¹⁸ in formula (II) have the same definitions as those in formula (I);

L¹ and L² independently represent

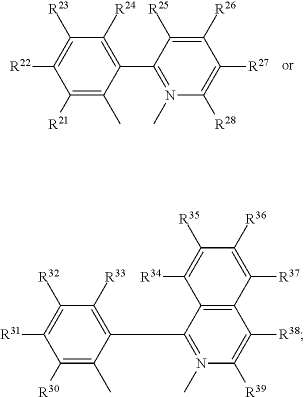

and

R²¹, R²², R²³, R²⁴, R²⁵, R²⁶, R²⁷, R²⁸, R³⁰, R³¹, R³², R³³, R³⁴, R³⁵, R³⁶, R³⁷, R³⁸, and R³⁹ independently represent H or an organic group.

Preferably, at least one of R²¹, R²², R²³, R²⁴, R²⁵, R²⁶, R²⁷, and R²⁸ is halogen. Preferably, at least one of R³⁰, R³¹, R³², R³³, R³⁴, R³⁵, R³⁶, R³⁷, R³⁸, and R³⁹ is halogen.

By virtue of the molecular structure design of the phenylsilyl phosphine compound in the present invention, when the phenylsilyl phosphine compound incorporates iridium to form the iridium complex, energy gap between the highest occupied molecular orbital (HOMO) and the lowest unoccupied molecular orbital (LUMO) of the iridium complex is capable of being adjusted so as to enhance light absorption of the iridium complex with different wavelengths. Besides, by including silicon into the molecular structure of the phenylsilyl phosphine compound, conjugation between the benzene ring in the phenyl phosphine ligand and the oxygen atom with lone pair electrons in the iridium complex can be blocked, thereby reducing the ligand-to-ligand charge transfer effect of the iridium complex and further improving the light emitting efficiency of the iridium complex.

Different iridium complexes of the present invention may be prepared by choosing respective reactants and under appropriate reaction conditions. Accordingly, a method for preparing the iridium complex includes the following steps:

(1) reacting a 1-phenylisoquinoline based compound or 2-phenylpyridine based compound with an iridium source under heating to form an intermediate; and

(2) mixing the phenylsilyl phosphine compound, an alcohol, and the intermediate followed by reacting in the presence of a catalyst under heating so as to obtain the iridium complex.

Preferably, the 1-phenylisoquinoline based compound is 1-phenylisoquinoline, and the 2-phenylpyridine based compound is 2-(4,6-difluorophenyl)pyridine or 2-phenylpyridine. Preferably, the iridium source is iridium (III) chloride hydrate (IrCl₃.H₂O). The alcohol is used to provide the oxygen atom bonding Si and Ir in the iridium complex. Since the step (2) is conducted at high temperature, boiling point of the alcohol needs to be sufficiently high. Preferably, the alcohol is 2-methyloxyethanol. Preferably, the catalyst is sodium carbonate, potassium acetate, or sodium acetate.

### EXAMPLES

### Synthesis Example 1

0.10 gram (0.087 mmole) of Pd(PPh₃)₄ was placed in a 100 ml two-neck bottle, followed by adding 3.7 grams (20 mmoles) of diphenyl phosphine, toluene, 3.1 ml (22 mmoles) of triethylamine, and 2.6 ml (20 mmoles) of 1-bromo-2-iodo-benzene into the two-neck bottle in nitrogen atmosphere to obtain a mixture. The mixture was then heated up to 80° C. and reacted for 12 hours. After the reaction was finished, a resultant reaction product was dried in vacuum to remove toluene. Then, the reaction product was extracted with a solvent which contains 50 ml of dichloromethane and 50 ml of water for three times. Organic layers were collected, followed by drying the organic layers in vacuum. Column chromatography was then performed for purifying the organic layers with an eluent which includes ethyl acetate and hexane at a ratio of 1:20. 6.7 grams (20 mmoles) of a white solid was then obtained with a yield of 98%.

The spectrum analysis for the white solid is:

¹H NMR (400 MHz, CD₂Cl₂, 298K), δ (ppm): 7.66˜7.63 (m, 1H), 7.38˜7.36 (m, 6H), 7.31˜7.20 (m, 4H), 7.19˜7.21 (m, 2H), 6.75˜6.77 (m, 1H). The chemical structure of the white solid is:

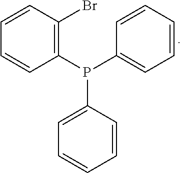 [SMILES: Brc1ccccc1P(c1ccccc1)c1ccccc1]

2.3 grams (6.6 mmoles) of the white solid was placed into a 100 ml round-bottom flask, followed by adding 50 ml of tetrahydrofuran and cooling to −78° C. 2.9 ml (7.25 mmoles) of 2.5 M n-Butyllithium solution in hexane was then added into the flask followed by reacting for 30 minutes to obtain a transparent solution with an orange-red color. 1.5 ml (7.7 mmoles) of diphenylchlorosilane was added into the flask, followed by raising temperature to room temperature and reacting for 12 hours until the color of the solution in the flask turned into light-yellow. The light-yellow solution was then dried in vacuum and extracted by a solvent containing 50 ml of dichloromethane and 50 ml of water for three times. Organic layers were collected, dried in vacuum and recrystallized using a solvent including dichloromethane and hexane, and 2.0 grams (4.5 mmoles) of a white solid was obtained with a yield of 70%.

The spectrum analysis of the white solid is:

¹H NMR (400 MHz, CDCl₃, 298K), δ (ppm): 7.51˜7.48 (m, 5H), 7.36˜7.22 (m, 15H), 7.10 (t, J_{HH}=6.0 Hz, 4H), 5.82 (d, J_{HH}=6.8 Hz, 1H). The chemical structure of the white solid is

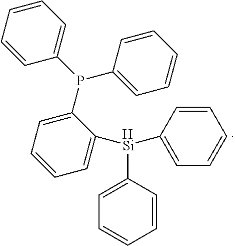

### Synthesis Example 2

0.10 gram (0.087 mmole) of Pd(PPh₃)₄ was placed in a 100 ml two-neck bottle, followed by adding 3.7 grams (20 mmoles) of diphenyl phosphine, toluene, 3.1 ml (22 mmoles) of triethylamine, and 2.6 ml (20 mmoles) of 1-bromo-2-iodo-benzene into the two-neck bottle in a nitrogen gas atmosphere to obtain a mixture. The mixture was heated up to 80° C. and reacted for 12 hours. After the reaction is finished, a resultant reaction product was dried in vacuum to remove toluene. Then, the reaction product was extracted with a solvent which contains 50 ml of dichloromethane and 50 ml of water for three times. Organic layers were collected, followed by drying the organic layers in vacuum. Column chromatography was then performed for purifying the organic layer with an eluent which includes ethyl acetate and hexane at a ratio of 1:20. 6.7 grams of (20 mmoles) of a white solid was then obtained with a yield of 98%.

The spectrum analysis for the white solid is:

¹H NMR (400 MHz, CD₂Cl₂, 298K), δ (ppm): 7.66˜7.63 (m, 1H), 7.38”7.36 (m, 6H), 7.31˜7.20 (m, 4H), 7.19˜7.21 (m, ²H), 6.75˜6.77 (m, 1H). The chemical structure of the white solid is:

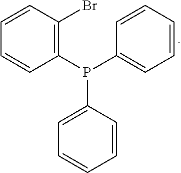 [SMILES: Brc1ccccc1P(c1ccccc1)c1ccccc1]

2.0 grams (5.9 mmoles) of the white solid was placed into a 100 ml round-bottom flask, followed by adding 50 ml of tetrahydrofuran and cooling to −78° C. 2.6 ml (6.5 mmoles) of 2.5 M n-butyllithium solution in hexane was then added into the flask followed by reacting for 30 minutes to obtain a transparent solution with orange-red color. 0.8 ml (7.2 mmoles) of dimethylchlorosilane was then added into the flask, followed by raising temperature to room temperature and reacting for 12 hours until the color of the solution in the flask turned into light-yellow. The light-yellow solution was then dried in vacuum and extracted by a solvent containing 50 ml of dichloromethane and 50 ml of water for three times. Organic layers were collected, dried in vacuum and recrystallized using a solvent including dichloromethane and hexane, and 1.6 grams (5.0 mmoles) of a white solid was obtained with a yield of 90%.

The spectrum analysis of the white solid is:

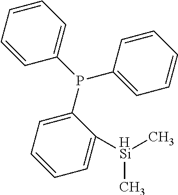

### Synthesis Example 3

3.53 grams (10 mmoles) of IrCl₃.H₂O was placed into a round-bottom flask, followed by adding 2.2 equivalents of 1-phenylisoquinoline to form a mixture. The mixture was then heated under reflux for 16 hours to 24 hours. After the reaction was finished, the mixture was cooled to room temperature, followed by adding deionized water to generate a precipitate. The precipitate was then filtered to obtain a filter cake. The filter cake was sequentially washed with ice methanol and ethyl ether and was dried to obtain a product. The chemical structure of the product is

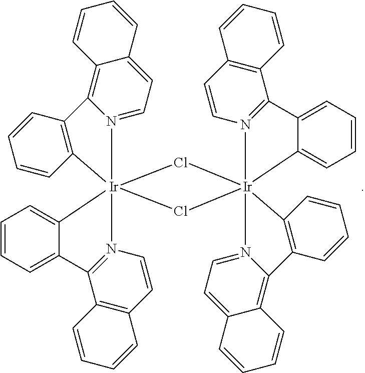

### Synthesis Example 4

3.53 grams (10 mmoles) of IrCl₃.H₂O was placed into a round-bottom flask, followed by adding 2.2 equivalents of 2-phenylpyridine to form a mixture. The mixture was then heated under reflux for 16 hours to 24 hours. After the reaction was finished, the mixture was cooled to room temperature, followed by adding deionized water to generate a precipitate. The precipitate was then filtered to obtain a filter cake. The filter cake was sequentially washed with ice methanol and by ethyl ether and was dried to obtain a product. The chemical structure of the product is

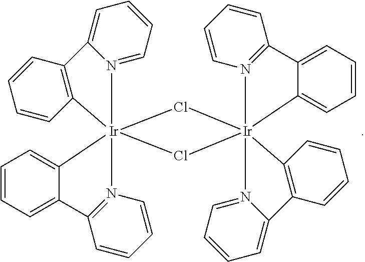

### Synthesis Example 5

3.53 grams (10 mmoles) of IrCl₃.H₂O was placed into a round-bottom flask, followed by adding 2.2 equivalents of 2-(4,6-difluorophenyl)pyridine to form a mixture. The mixture was then heated under reflux for 16 hours to 24 hours. After the reaction was finished, the mixture was cooled to room temperature, followed by adding deionized water to generate a precipitate. The precipitate was then filtered to obtain a filter cake. The filter cake was sequentially washed with ice methanol and by ethyl ether and was dried to obtain a product. The chemical structure of the product is

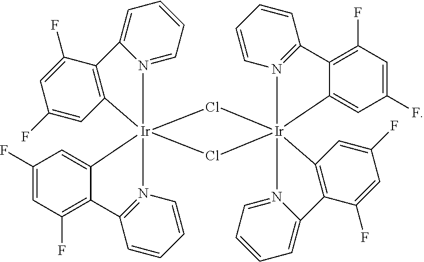

### Preparation of Iridium Complex

### Example 1

500 mg (0.39 mmole) of the product of Synthesis Example 3 was placed into a 50 ml round-bottom flask, followed by adding 380 mg (0.86 mmole) of the white solid of Synthesis Example 1, 410 mg (3.9 mmoles) of sodium carbonate, and 10 ml of 2-methyloxyethanol into the flask to form a mixture. The mixture was then heated under reflux for 2 hours. After the reaction was finished, the mixture was cooled to room temperature, and 2-methyloxyethanol was removed. Column chromatography was then performed for purifying the mixture with an eluent, which contains ethyl acetate and hexane at a ratio of 1:3, and a product was obtained. The product was then recrystallized using a solvent including ethyl acetate and hexane, and 530 mg (0.50 mmole) of a red iridium complex (abbreviated as complex C-1) was obtained with a yield of 64%.

The spectrum analysis of the complex C-1 is: ¹H NMR (400 MHz, CD₂Cl₂, 298K), δ (ppm) 9.31 (d, J_{HH}=6.4 Hz, 1H). 8.82 (d, J_{HH}=8.4 Hz, 1H), 8.74 (d, J_{HH}=6.4 Hz, 1H). 8;63 (d, J_{HH}=8.4 Hz, 1H), 8.11 (d, J_{HH}=7.6 Hz, 1H), 7.88 (t, J_{HH}=7.2 Hz, 2H), 7.86˜7.64 (m, 5H), 7.58˜7.55 (m, 3H), 7.48 (t, J_{HH}=8.4 Hz, 2H), 7.40 (t, J_{HH}=7.6 Hz, 1H), 7.31˜7.25 (m, 5H), 7.19˜7.14 (m, 4H), 6.93˜6.89 (m, 2H), 6.80˜6.69 (m, 5H), 6.62˜6.66 (m, 2H), 6.49˜6.39 (m, 6H), 6.3 (d, J_{HH}=7.6 Hz, 1H), 6.03 (t, J_{HH}=6.4 Hz, 1H). The chemical structure of the complex C-1 is

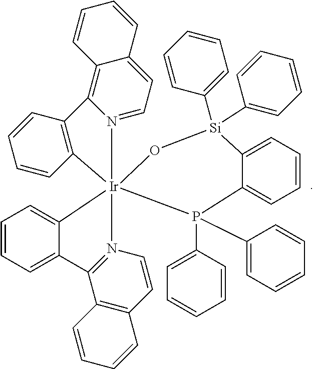

### Example 2

300 mg (0.280 mmole) of the product of Synthesis Example 4 was placed into a 50 ml round-bottom flask, followed by adding 250 mg (0.56 mmole) of the white solid of Synthesis Example 1, 300 mg (2.8 mmoles) of sodium carbonate, and 10 ml of 2-methyloxyethanol into the flask to form a mixture. The mixture was then heated under reflux for 2 hours. After the reaction was finished, the mixture was cooled to room temperature and 2-methyloxyethanol was removed. Column chromatography was then performed for purifying the mixture with an eluent, which contains ethyl acetate and hexane at a ratio of 1:3, and a product was obtained. The product was then recrystallized using a solvent including ethyl acetate and hexane, and 170 mg (0.50 mmole) of a yellow-color iridium complex (abbreviated as complex C-2) was obtained with a yield of 64%.

The spectrum analysis of the complex C-2 is ¹H NMR (400 MHz, CD₂Cl₂, 298K), δ (ppm): 9.19 (d, J_{HH}=5.6 Hz, 1H), 8.86 (d, J_{HH}=6 Hz, 1H), 7.89 (d, J_{HH}=8 Hz, 1H), 7.78˜7.72 (m, 2H), 7.56˜7.55(m, 4H), 7.49˜7.45 (m, 4H), 7.40˜7.29 (m, 3H), 7.22˜7.15 (m, 6H), 7.08˜7.01 (m, 2H), 6.88˜6.72 (m, 8H), 6.65˜6.58 (m, 4H), 6.45 (t, J_{HH}=7.6 Hz, 2H), 6.33 (d, J_{HH}=6.4 Hz, 1H), 5.88 (m, 1H). The chemical structure of the complex C-2 is

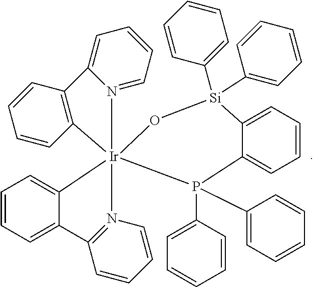

### Example 3

400 mg (0.330 mmole) of the product of Synthesis Example 5 was placed into a 50 ml round-bottom flask, followed by adding 310 mg (0.70 mmole) of the white solid of Synthesis Example 1, 350 mg (3.3 mmoles) of sodium carbonate, and 10 ml of 2-methyloxyethanol into the flask to form a mixture. The mixture was then heated under reflux for 2 hours. After the reaction was finished, the mixture was cooled to room temperature and 2-methyloxyethanol was removed. Column chromatography was then performed for purifying the mixture with an eluent, which contains ethyl acetate and hexane at a ratio of 1:3, and a product was obtained. The product was then recrystallized using a solvent including ethyl acetate and hexane, and 470 mg (0.46 mmole) of a yellow-color iridium complex (abbreviated as complex C-3) was obtained with a yield of 70%.

The spectrum analysis of the complex C-3 is: ¹H NMR (400 MHz, CD₂Cl₂, 298K), δ (ppm): 9.06 (d, J_{HH}=5.2 Hz, 1H), 8.81 (d, J_{HH}=6.0 Hz, 1H), 8.07 (d, J_{HH}=6.4 Hz, 1H), 7.73˜7.66 (m, 3H), 7.49˜7.39 (m, 7H), 7.28˜7.23 (m, 8H), 7.10˜7.08 (m, 2H), 6.92˜6.76 (m, 7H), 6.52 (t, J_{HH}=6.4 Hz, 1H), 6.48 (t, J_{HH}=8.4 Hz, 2H). 6.46 (t, J_{HH}=8.0 Hz, 1H), 6.23 (t, J_{HH}=8.0 Hz, 1H), 5.72 (d, J_{HH}=9.2 Hz, 1H). The chemical structure of the complex C-3 is

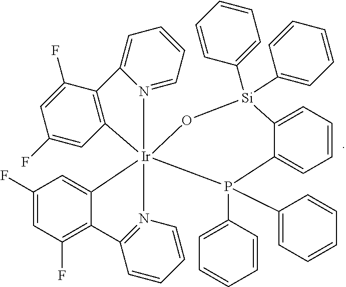

### Example 4

400 mg (0.31 mmole) of the product of Synthesis Example 3 was placed into a 50 ml round-bottom flask, followed by adding 210 mg (0.66 mmole) of the white solid of Synthesis Example 2, 330 mg (3.1 mmoles) of sodium carbonate, and 10 ml of 2-methyloxyethanol into the flask to form a mixture. The mixture was then heated under reflux for 2 hours. After the reaction was finished, the mixture was cooled to room temperature and 2-methyloxyethanol was removed. Column chromatography was then performed for purifying the mixture with an eluent, which contains ethyl acetate and hexane at a ratio of 1:1, and a product was obtained. The product was then recrystallized using a solvent including ethyl acetate and hexane, and 470 mg (0.46 mmole) of a red-color iridium complex (abbreviated as complex C-4) was obtained with a yield of 61%.

The spectrum analysis of the complex C-4 is: ¹H NMR (400 MHz, CD₂Cl₂, 298K), δ (ppm): 8.90 (q, J_{HH}=8.0 Hz, 3H), 8.79 (d, J_{HH}=6.4 Hz, 1H), 8.16 (t, J_{HH}=6.8 Hz, 2H), 7.85˜7.81 (m, 2H), 7.74˜7.68 (m, 4H), 7.51˜7.48 (m, 3H), 7.38 (t, J_{HH}=7.2 Hz, 1H), 7.31 (t, J_{HH}=7.2 Hz, 1H), 7.20˜7.14 (m, 3H), 7.00˜6.95 (m, 4H), 6.89 (t, J_{HH}=8 Hz, 1H), 6.79 (t, J_{HH}=7.6 Hz, 1H), 6.67 (q, J_{HH}=6.8, 2H), 6.60˜6.52 (m, 3H), 6.45 (t, J_{HH}=7.2 Hz, 2H), 5.91˜5.89 (m, 1H), 0.32 (s, 3Hz), −0.79 (s, 3H). The chemical structure of the complex C-4 is

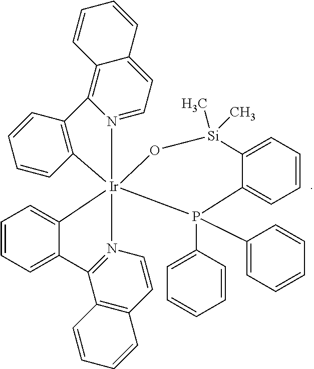

### Example 5

200 mg (0.19 mmole) of the product of Synthesis Example 4 was placed into a 50 ml round-bottom flask, followed by adding 130 mg (0.39 mmole) of the white solid of Synthesis Example 2, 200 mg (1.9 mmoles) of sodium carbonate, and 10 ml of 2-methyloxyethanol into the flask to form a mixture. The mixture was then heated under reflux for 2 hours. After the reaction was finished, the mixture was cooled to room temperature and 2-methyloxyethanol was removed. Column chromatography was then performed for purifying the mixture with an eluent, which contains ethyl acetate and hexane at a ratio of 2:1, and a product was obtained. The product was then recrystallized using a solvent including ethyl acetate and hexane, and 110 mg (0.13 mmole) of a yellow-color iridium complex (abbreviated as complex C-5) was obtained with a yield of 36%.

The spectrum analysis of the complex C-5 is: ¹H NMR (400 MHz, CD₂Cl₂, 298K), δ (ppm): 8.82 (d, J_{HH}=5.2 Hz, 1H), 8.65 (d, J_{HH}=5.6 Hz, 1H), 7.93 (d, J_{HH}=7.6 Hz, 1H), 7.73˜7.63 (m, 3H), 7.56 (t, J_{HH}=7.6 Hz, 1H), 7.51˜7.43 (m, 4H), 7.37 (t, J_{HH}=6 Hz, 1H), 7.30 (t, J_{HH}=7.2 Hz, 1H), 7.16 (t, J_{HH}=7.6 Hz, 4H), 6.94˜6.81 (m, 4H), 6.73˜6.50 (m, 8H), 5.75˜5.72 (m, 1H), 0.276 (s, 3H), −0.694 (s, 3H). The chemical structure of the complex C-5 is

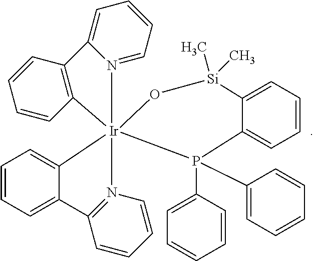

### Example 6

200 mg (0.16 mmole) of the product of Synthesis Example 5 was placed into a 50 ml round-bottom flask, followed by adding 170 mg (1.6 mmoles) of the white solid of Synthesis Example 2, 260 mg (2.5 mmoles) of sodium carbonate, and 10 ml of 2-methyloxyethanol into the flask to form a mixture. The mixture was then heated under reflux for 2 hours. After the reaction was finished, the mixture was cooled to room temperature and 2-methyloxyethanol was removed. Column chromatography was then performed for purifying the mixture with an eluent, which contains ethyl acetate and hexane at a ratio of 2:5, and a product was obtained. The product was then recrystallized using a solvent including ethyl acetate and hexane, and 218 mg (0.24 mmole) of a yellow-color iridium complex (abbreviated as complex C-6) was obtained with a yield of 75%.

The spectrum analysis of the complex C-6 is: ¹H NMR (400 MHz, CD₂Cl₂, 298K), δ (ppm): 8.84 (d, J_{HH}=5.2 Hz, ¹H), 8.65 (d, J_{HH}=6 Hz, 1H), 8.34 (d, J_{HH}=8.4 Hz, 1H), 8.09 (d, J_{HH}=8.4 Hz, 1H), 7.73 (t, J_{HH}=8 Hz, 1H), 7.62 (t, J_{HH}=7.2 Hz, 1H), 7.51˜7.48 (m, 1H), 7.44˜7.34 (m, 4H), 7.22˜7.19 (m, 4H), 6.93 (td, J_{HH}=7.6 Hz, J_{HH}=2 Hz, 2H), 6.84 (t, J_{HH}=8.4 Hz, 1H), 6.70 (t, J_{HH}=6.4 Hz, 1H), 6.64 (t, J_{HH}=5.2 Hz, 1H), 6.54 (t, J_{HH}=9.2 Hz, 2H), 6.44˜6.38 (m, 1H), 6.26˜6.20 (m, 1H), 6.00 (dd, J_{HH}=9.2H, J_{HH}=2.4 Hz, 1H), 5.21˜5.18 (m, 1H), 0.29 (s, 3H), −0.68 (s, 3H). The chemical structure of the complex C-5 is

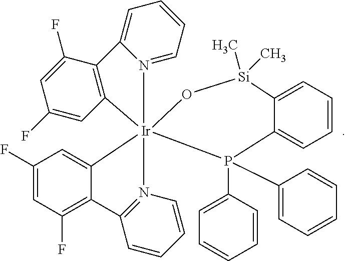

### Comparative Examples 1˜3

Iridium complexes for Comparative Examples 1 to 3 were prepared based on the method disclosed in US Patent Application Publication No. 2008/0217582 and chemical structures thereof are shown below:

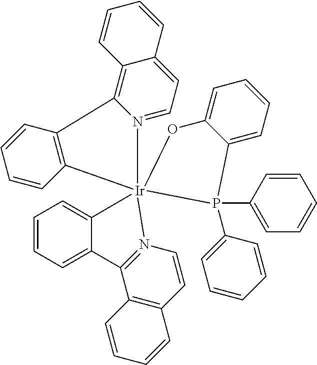

### Comparative Example 1

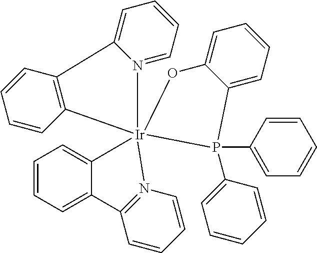

### Comparative Example 2

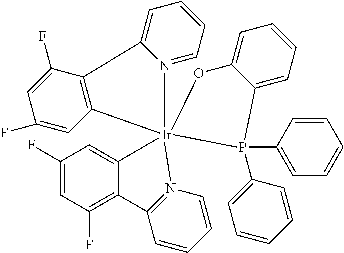

### Comparative Example 3

### Comparative Examples 4˜5

Iridium complexes for Comparative Examples 4 and 5 were prepared based on Taiwanese Patent Application Publication No. 201037057, and chemical structures of the iridium complexes of Comparative Examples 4 and 5 are shown below:

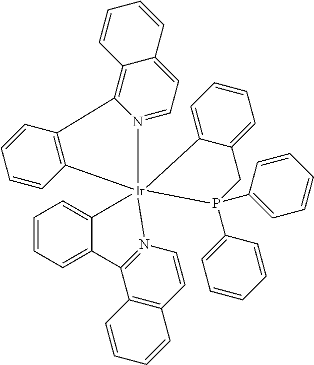

### Comparative Example 4

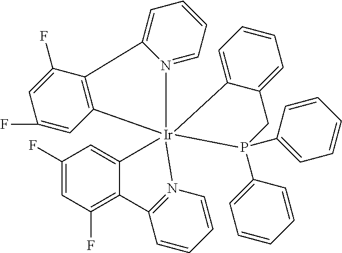

### Comparative Example 5

### <Measurements>

### 1. Molar Extinction Coefficient Measurement:

The iridium complexes for each of Examples 1 to 6 and Comparative Examples 1 to 5 were dissolved in dichloromethane, and the respective molar extinction coefficient thereof was measured by utilizing an ultraviolet/visible Light Spectrophotometer (Hitachi, Model No.: U3900).

### 2. Quantum Efficiency (Quantum Yield) and Lifetime Measurement:

The iridium complex of each of Examples 1 to 6 and Comparative Examples 1 to 5 was subjected to measurements of quantum efficiency (Q.Y.) and lifetime (τ_{obs}). The radioactive decay rate (kᵣ) and nonradioactive decay rate (kₙᵣ) of the iridium complex for Examples 1 to 6 and Comparative Example 1 to 5 were obtained by substituting the values of Q.Y. and τ_{obs} into following formulas (1) and (2):

$$\begin{matrix}Q . Y . = \frac{{k}_{r}}{{k}_{r} + {k}_{nr}} & ( 1 ) \\ {τ}_{obs} = \frac{1}{{k}_{r} + {k}_{nr}} & ( 2 )\end{matrix}$$

The measurements of Q.Y. and τ_{obs} were performed using a phosphorescent spectrophotometer (Hitachi, Model No.: U-4500), and the scan range for wavelengths of light depended on light-emitting wavelengths of the iridium complex respectively. Results of the measurements are listed in Table 1.

TABLE 1

| | Peak | | | | |
|---|---|---|---|---|---|
| Iridium | Wavelength | | τ _{obs} | | |
| Complex | (λ, nm) | Q.Y. | (ns) | kr(s⁻¹ ) | kₙᵣ(s⁻¹ ) |
| Ex.1 | 644 | 0.26 | 1,570 | 1.63 × 10⁵ | 4.73 × 10⁵ |
| Ex.2 | 519 | 0.73 | 1,661 | 4.38 × 10⁵ | 1.64 × 10⁵ |
| Ex.3 | 501 | 0.62 | 919 | 6.79 × 10⁵ | 4.09 × 10⁵ |
| Ex.4 | 650 | 0.36 | 1,360 | 2.63 × 10⁵ | 4.72 × 10⁵ |
| Ex.5 | 530 | ~1 | 1,720 | 8.13 × 10⁵ | <<1 |
| Ex.6 | 505 | 0.59 | 656 | 8.98 × 10⁵ | 6.26 × 10⁵ |
| Comp. Ex.1 | 652 | 0.18 | 2,158 | 8.33 × 10⁵ | 3.80 × 10⁴ |
| Comp. Ex.2 | 515 | 0.09 | 108 | 8.33 × 10⁴ | 8.43 × 10⁶ |
| Comp. Ex.3 | 500 | 0.09 | 223 | 3.85 × 10⁵ | 4.1 × 10⁶ |
| Comp. Ex.4 | 600 | 0.86 | 3,440 | 2.5 × 10⁵ | 4.1 × 10⁵ |
| Comp. Ex.5 | 469 | 0.06 | 145 | 4.2 × 10⁵ | 6.5 × 10⁵ |

As shown in Table 1, the iridium complexes of Examples 1 to 6 indeed have improved light emitting efficiencies compared to the Comparative Examples.

To sum up, by virtue of the molecular structure design of the phenylsilyl phosphine compound in the present invention, when the phenylsilyl phosphine compound incorporates iridium to form the iridium complex, energy gap between the highest occupied molecular orbital (HOMO) and the lowest unoccupied molecular orbital (LUMO) of the iridium complex is capable of being adjusted so as to enhance light absorption of the iridium complex with different wavelengths. Besides, by including silicon into the molecular structure of the phenylsilyl phosphine compound, conjugation between the benzene ring in the phenyl phosphine ligand and the oxygen atom with lone pair electrons in the iridium complex can be blocked, thereby reducing the ligand to ligand charge transfer effect of the iridium complex and further improving the light emitting efficiency of the iridium complex.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

1. A phenylsilyl phosphine compound represented by formula (I): 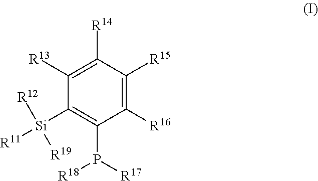
wherein:
R¹¹, R¹², R¹⁷, and R¹⁸ independently represent H, an alkyl group, or an aryl group;
R¹³, R¹⁴, R¹⁵, and R¹⁶ independently represent H, halogen, or an organic group;
R¹⁹ represents H, or O—R²⁰; and
R²⁰ represents H or a leaving group.

2. The phenylsilyl phosphine compound as claimed in claim 1, wherein R¹¹ and R¹² independently represent H, a methyl group or an optionally substituted phenyl group.

3. The phenylsilyl phosphine compound as claimed in claim 1, wherein R¹⁷ and R¹⁸ independently represent H, a methyl group or an optionally substituted phenyl group.

4. The phenylsilyl phosphine compound as claimed in claim 1, wherein the organic group is an electron withdrawing group or an electron donating group.

5. An iridium complex represented by formula (II): 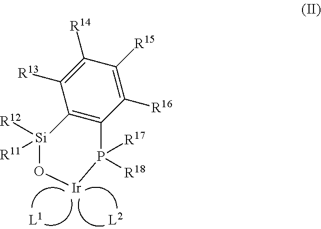
wherein:
R¹¹, R¹², R¹⁷, and R¹⁸ independently represent H, an alkyl group, or an aryl group;
R¹³, R¹⁴, R¹⁵, and R¹⁶ independently represent H, halogen, or an organic group;
L¹ and L² independently represent 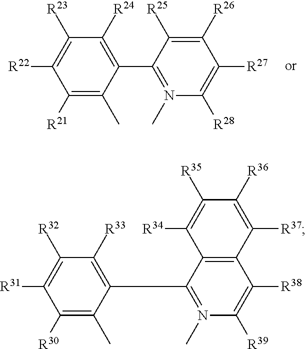
and
R²¹, R²², R²³, R²⁴, R²⁵, R²⁶, R²⁷, R²⁸, R³⁰, R³¹, R³², R³³, R³⁴, R³⁵, R³⁶, R³⁷, R³⁸, and R³⁹ independently represent H, halogen, or an organic group.

6. The iridium complex as claimed in claim 5, wherein R¹¹ and R¹² independently represent H, a methyl group or an optionally substituted phenyl group.

7. The iridium complex as claimed in claim 5, wherein R¹⁷ and R¹⁸ independently represent H, a methyl group or an optionally substituted phenyl group.

8. The iridium complex as claimed in claim 5, wherein the organic group represents an electron withdrawing group or an electron releasing group.

9. The iridium complex as claimed in claim 5, wherein at least one of R²¹, R²², R²³, R²⁴, R²⁵, R²⁶, R²⁷, and R²⁸ is halogen.

10. The iridium complex as claimed in claim 5, wherein at least one of R³⁰, R³¹, R³², R³³, R³⁴, R³⁵, R³⁶, R³⁷, R³⁸, and R³⁹ is halogen.
